(19) United States
(12) Patent Application Publication
(10) Pub. No.: US 2024/0070357 A1
(43) Pub. Date: Feb. 29, 2024

(54) METHODS AND DEVICES FOR PORE NETWORK DUPLICATION AND BLENDING

(71) Applicant: UNIVERSITY OF WYOMING, Laramie, WY (US)

(72) Inventors: Bradley MCCASKILL, Laramie, WY (US); Mohammad PIRI, Laramie, WY (US)

(21) Appl. No.: 18/239,533

(22) Filed: Aug. 29, 2023

Related U.S. Application Data
(60) Provisional application No. 63/401,995, filed on Aug. 29, 2022.

(51) Int. Cl. G06F 30/28

(52) U.S. Cl. CPC G06F 30/28

(57) ABSTRACT

A method and system for generating a heterogeneous plug for a porous media sample by one or more central processing units (CPUs), including duplicating one or more sample pore elements to fill one or more components of a heterogeneous plug, constructing a set of buffer zones between each of the one or more components, populating the set of buffer zones with one or more generated pore elements, the one or more generated pore elements based, at least in part, on the one or more sample pore elements, and connecting the one or more generated pore elements to the one or more components to generate the heterogeneous plug.

### CROSS-REFERENCE TO RELATED APPLICATIONS

This applications claims benefit of U.S. Provisional Patent Application No. 63/401,995, filed Aug. 29, 2022, the entirety of which is herein incorporated by reference.

### BACKGROUND

### Field

Aspects of the present disclosure generally relate to characterizing of porous media, and more particularly, to pore network duplication and blending to produce a heterogeneous plug representative of a porous media sample.

### Description of the Related Art

Modeling techniques for fluid flow through porous media are broadly implemented for petroleum resource development, materials engineering, food packaging, and medical technology development. Fluid flow modeling techniques may be equipped to illustrate both physical and chemical media properties like permeability, capillary pressure, fluid saturation, contact angle, wettability, or other similar properties, which may be used to characterize fluid behavior.

Although current techniques for modelling fluid flow through porous media are based on technological advancements made over many years, resultant models may still be tenuous representations of actual porous media. For example, fluid flow models of porous media exceeding a few millimeters may require a lower resolution implementation to match currently available computational capabilities. As a result, fluid flow models based on porous media of a larger scale may not accurately reflect physical and chemical properties of the media. Accordingly, there is an impetus to improve the accuracy of fluid flow modeling, including, for example: improving image processing techniques to allow for higher resolution model input and model output, improving image processing techniques to allow for more accurate model input and model output, enhancing computational processing capability to reduce computational expense, enhancing computational processing capability increase modeling speed, increasing automation for iterative modeling steps, improving model capability for dynamic modeling of different fluid flow environments, improving model capability for dynamic modeling of larger fluid flow environments, and the like.

Consequently, there exists a need for further improvements in fluid flow modeling of porous media to overcome the aforementioned technical challenges and other challenges not mentioned.

### SUMMARY

One aspect of the present disclosure provides a method for pore network stitching by one or more central processing units (CPU). The method may include duplicating one or more sample pore elements to fill one or more components of a heterogeneous plug. The method may include constructing a set of buffer zones between each of the one or more components. The method may include populating the set of buffer zones with one or more generated pore elements, the one or more generated pore elements based, at least in part, on the one or more sample pore elements. The method may include connecting the one or more generated pore elements to the one or more components to generate the heterogeneous plug.

One aspect of the present disclosure provides an apparatus for porous media characterization comprising a memory and one or more CPU, the one or more CPUs configured to cause the apparatus to perform a method. The method may include duplicating one or more sample pore elements to fill one or more components of a heterogeneous plug. The method may include constructing a set of buffer zones between each of the one or more components. The method may include populating the set of buffer zones with one or more generated pore elements, the one or more generated pore elements based, at least in part, on the one or more sample pore elements. The method may include connecting the one or more generated pore elements to the one or more components to generate the heterogeneous plug.

Other aspects provide: an apparatus operable, configured, or otherwise adapted to perform the aforementioned methods as well as those described elsewhere herein; a non-transitory, computer-readable media comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and an apparatus comprising means for performing the aforementioned methods as well as those described elsewhere herein. By way of example, an apparatus may comprise a processing system, a device with a processing system, or processing systems cooperating over one or more message passing interfaces.

### BRIEF DESCRIPTION OF THE DRAWINGS

So that the manner in which the above recited features of the present disclosure can be understood in detail, a more particular description of the disclosure, briefly summarized above, may be had by reference to aspects, some of which are illustrated in the appended drawings. It is to be noted, however, that the appended drawings illustrate only example aspects and are therefore not to be considered limiting of its scope, may admit to other equally effective aspects.

FIG. 1A depicts an example ball and stick representation of a pore network model extracted from a porous media sample made of sandstone.

FIG. 1B depicts an example 2D slice of a set of high-resolution porous media image taken by a scanning instrument from a single rock sample and segmented for characterization, and a ball and stick representation of a pore network extracted from them.

FIG. 2 depicts an example core-flooding instrument for determining the physical and chemical characteristics of a porous media sample.

FIG. 3 depicts an example heterogeneous plug generation procedure for characterization of porous media by one or more central processing units (CPU).

FIG. 4 depicts an example workflow for constructing heterogeneous plugs according to aspects of the present disclosure.

FIG. 5 depicts an example heterogeneous plug generated from representative pore networks of sand packs, according to aspects of the present disclosure.

FIG. 6 depicts an example heterogeneous plug obtained using pore network duplication, stitching, and stochastic blending, according to aspects of the present disclosure.

FIG. 7 illustrates predicted relative permeability curves for primary drainage and imbibition obtained using quasi-static pore network modeling, according to aspects of the present disclosure.

FIG. 8 is a flow diagram illustrating certain operations by one or more CPUs, according to certain aspects of the present disclosure.

FIG. 9 is an example device for constructing heterogeneous plugs.

To facilitate understanding, identical reference numerals have been used, where possible, to designate identical elements that are common to the figures. It is contemplated that elements and features of one aspect may be beneficially incorporated in other aspects without further recitation.

### DETAILED DESCRIPTION

In the following, reference is made to aspects of the disclosure. However, it should be understood that the disclosure is not limited to specifically described aspects. Instead, any combination of the following features and elements, whether related to different aspects or not, is contemplated to implement and practice the disclosure. Furthermore, although aspects of the disclosure may achieve advantages over other possible solutions and/or over the prior art, whether or not a particular advantage is achieved by a given aspect is not limiting of the disclosure. Thus, the following aspects, features, embodiments, and advantages are merely illustrative and are not considered elements or limitations of the appended claims except where explicitly recited in a claim(s). Likewise, a reference to “the disclosure” shall not be construed as a generalization of any inventive subject matter disclosed herein and shall not be considered to be an element or limitation of the appended claims except where explicitly recited in a claim(s).

The present disclosure relates to techniques for physical characterization of porous media. Specifically, the techniques discussed herein may be implemented for non-destructive extraction of geometry information, capillary pressure and wettability information from porous media samples. The porous media sample may comprise a digital rock sample, a rock sample, a core sample, a plastic sample, a tissue sample, a rough-walled fracture space, or any other organic or inorganic sample having pore space ascertainable through imaging techniques.

A thorough grasp of fluid flow through porous spaces of certain materials may be consequential to enhancing technical efficacy of fluid flow techniques in a wide range of industries. Models of fluid flow are useful to describe physical and chemical characteristics of a porous material and may help to highlight the material's optimal usage. Often, networks of pores within a material are extremely small (e.g., microscale in size). Techniques for characterizing these pore networks are hindered by the computational expense of modeling at a microscale. To alleviate computational burdens, pore network modelling techniques often implement generalized characterization techniques at expense of model accuracy. Extrapolation errors caused by such imprecise characterization may result in mischaracterization of physical and chemical characteristics of the porous material. In many cases, these errors render such models impractical for regular use. Accordingly, ideal modeling of fluid flow through porous media would allow for rapid, accurate characterization of microscale pore spaces that may be performed without inhibitive computational expense.

Aspects of the present disclosure provide techniques for generating heterogeneous digital representations of porous media (e.g., heterogeneous plugs) that replicate the key physical properties of heterogeneous porous media samples. Specifically, one or more processors may be configured to replicate and merge sub-networks that represent distinct physical formations (e.g., layering, facies, sub-structures) within of the sample to mimic the structure of the porous media sample. Additionally, the one or more processors may generate these heterogeneous plugs based on porous media samples, which may be used to predict physical properties of large-scale bodies from which the porous media sample is derived when physical samples of the large scale bodies are unavailable.

Aspects of the present disclosure provide techniques for pore network duplication, stitching, and stochastic blending. Specifically, one or more processors may be configured to generate heterogeneous digital representations of porous media that reflect the local topology and heterogeneity of the entire sample. Additionally, aspects of the present disclosure may be parallelized to optimize computational performance.

Implementation of techniques for efficiently generating high-resolution pore networks as described herein may enhance pore network modelling functionality by reducing porous material characterization errors to the benefit of all users seeking a more comprehensive understanding of any given porous material.

### Introduction to Pore Network Modeling

Modeling techniques for fluid flow through porous media may illustrate both physical and chemical porous media properties. Models of porous media may be used to ascertain permeability, capillary pressure, fluid saturation, wettability, buoyancy, and the like to a greater degree of accuracy more comparable to physical flooding of a porous media sample. Additionally, physical and chemical properties determined using pore network modeling techniques may be used to characterize in-situ fluid behavior as it travels through the porous media under a wide variety of wettability and flooding conditions. These conditions are not typically accessible to users performing conventional physical flooding characterization techniques.

Permeability is the tendency of the porous media to allow liquids to flow through the porous media. Capillary pressure is the pressure difference existing across the interface separating two immiscible fluids. Fluid saturation is the measurement of fluid present in the pore spaces of the porous media. Contact angle is a measured angle between a fluid-fluid or a fluid-gas interface at a point where it meets a solid surface. Wettability is the ability of a liquid to maintain contact with a solid surface. Wettability may vary depending on wettability conditions and the type of wetting liquid present in the porous media sample. For example, a water-wet medium may show a lower wetting affinity to the oil phase than an oil-wet medium, where higher or lower wetting is determined with respect to a given phase. In certain cases, the correlation between wettability and viscosity ratio may not be straightforward, as there may be water or oil wet conditions with similar viscosities.

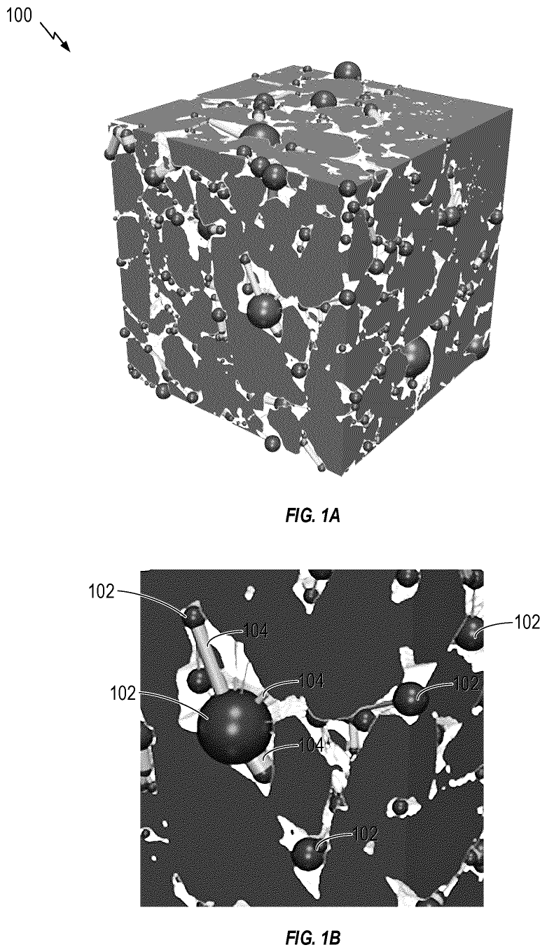

A modeled pore network is a practical description of a porous medium targeted for fluid flow modeling. FIG. 1A illustrates an example section of a pore network extracted from porous sandstone. The section of the pore network describes the porosities of various size and shape present in that portion of the sandstone, and may be used to model fluid flow through those porosities for various wettability conditions. Three-dimensional (3D) portions of a pore network model may more accurately characterize the porous media sample either alone or in combination with other 3D portions of the pore network model.

Pore network models (e.g., of FIG. 1A) may be extracted from images of a targeted porous medium and used to model multi-phase fluid flow using physically-based displacement mechanisms (PBDMs) across pores defined in a pore network. PBDMs may represent an estimated displacement of a modeled fluid in response to movement of another fluid or gas within the pore network. As immiscible phases react with one another throughout the pore network during fluid flooding, PBDMs are induced where, for example, capillary pressure across a meniscus exceeds the wettability constraints on either phase. Fluid saturation, contact angle, buoyancy, and the like may also affect PBDMs throughout a pore network. By utilizing a pore network model extracted from a porous media sample, a user is able to ascertain PBDMs through the porous media sample under a wide variety of wettability conditions in order to ultimately obtain, for example, useful permeabilities for a larger sample of the porous medium without degrading a porous media sample via repeated physical flooding.

To properly generate PBDMs at a pore scale for the targeted porous media, imaging may capture complex geometries of the targeted porous media at a resolution sufficiently high to retain acceptable accuracy. An example of these geometries is illustrated in FIG. 1B. Pores may be defined as a complex polyhedron having at least a center 102 and spherical and effective diameters. Connective throats 104 between pores may also be defined. In many cases, image resolution may be in micrometers to capture applicable pore detail. High-resolution pore models enable accurate rendering of the fluid flow characteristics described above as ascertained at each pore and for each PBDM.

PBDMs may occur upon flooding or draining of a pore network model, where aqueous phase injection or removal is iteratively simulated through the pore network. Aqueous flooding and aqueous draining may be implemented in various modeled wettability conditions, where certain fluids are present prior to the start of a simulation. Wettability conditions may include at least water-wet, oil-wet, or mixed-wet conditions. During aqueous flooding, injected water may displace immiscible fluid preexisting in the pore network model. During aqueous draining, injected immiscible fluid may displace water preexisting in the pore network model. In certain cases, flooding and draining may be fluid flooding and fluid draining. In some cases, the fluid is oil.

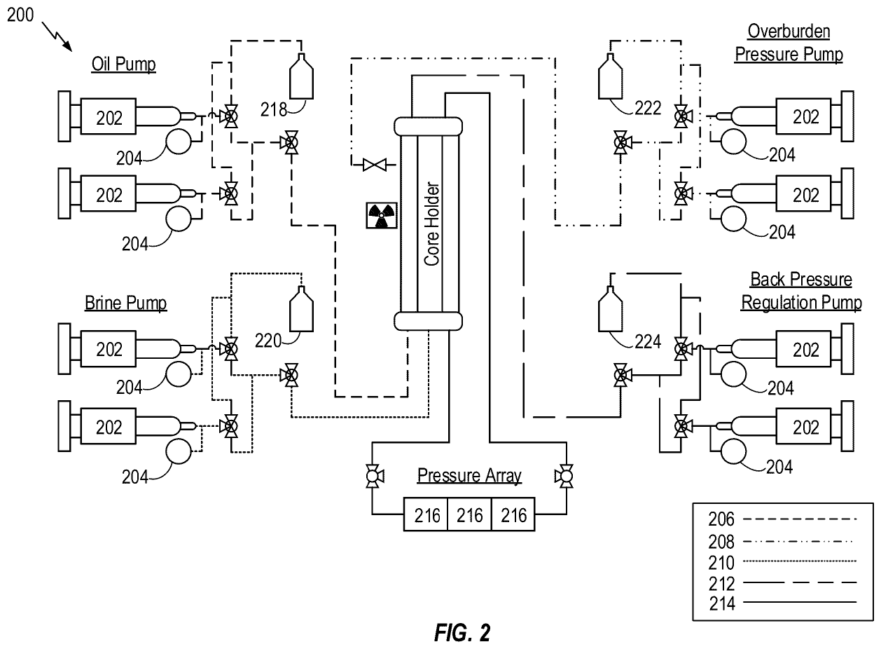

Flooding or draining of a pore network model may be simulated based in part on scanned images of physical flooding implemented by a flooding instrument 200 of FIG. 2. In some cases, a porous media may undergo a core-flooding experiment to establish an irreducible water saturation, a residual oil saturation, or both. Core-flooding is enabled by a set of pumps 202, rupture disks 204, pump lines 206-214, differential pressure transducers 216, and source buckets 218-222 working in tandem to flood a porous media sample loaded in a core holder. In some cases, a scanning instrument (e.g., a micro computed tomography (micro-CT) scanner) captures a dry reference image prior to flooding. Scanning occurs in a field of view defined within the core holder. The porous media sample may be flooded with brine from bucket 220 via the brine tubing line 206 and scanned again to ensure that the porous media sample is fully saturated. Once the brine flooding is complete, the absolute permeability of the porous media sample may be obtained. The oil flooding may be performed alongside additional brine flooding. Any fluid expelled as a result of overburden pressure (i.e., pressure that compacts pore space and reduces permeability) is transported via the confining fluid line 208 and collected in bucket 222. Any fluid expelled as a result of the flooding procedure is transported via the effluent fluid line 212 and collected in bucket 224. In many cases, core sample pressure may be iteratively adjusted during flooding. Pressure may be recorded by one or more differential pressure transducers 216 coupled to the core holder via a transducer line 214.

Scanned images obtained from flooding procedures performed by the flooding instrument 200 of FIG. 2 may be used to extract a pore map representative of the porous media sample prior to, during, or after flooding. The images may be processed to determine characteristics of fluid flow through the porous media sample. In many cases, the images may also be used to extract a representative pore network model.

Imaging of porous media is typically performed using micro-CT imaging. In many cases, commercial micro-CT scanners (e.g., Zeiss scanners) are available for imaging necessary to perform pore network modelling. Images of porous media taken by micro-CT scanners are at a sufficiently high resolution to create a microscale digital image of the porous media.

In the current state of the art, there exists a challenge of extracting porous media characteristics in a manner precise and repeatable to ensure the ultimate stability of future simulations. Currently, techniques for porous media characterization require lengthy step-wise processing known to incur undue computational expense and introduce instability to characterization of the porous media sample. As a result, users may not be able to rely on characterization output to simulate flow conditions in a useful way.

### Aspects Related to Pore Network Duplication and Blending

Fluid flow modelling through porous media is often utilized to enhance petroleum resource development. In recent years, global demand for energy resources has mobilized development of unconventional petroleum reservoirs as targets for hydrocarbon extraction. Example geological formations that comprise these newly developed hydrocarbon reservoirs are ultra-tight shale formations resistant to primary petroleum extraction techniques. A matrix of an ultra-tight unconventional shale reservoir may be characterized by low permeability and low porosity. To extract hydrocarbons from the ultra-tight shale matrix, secondary and tertiary petroleum extraction techniques seek to maximize oil production through the microscale pore networks that comprise a substantial amount of the porosity in the shale matrix.

A robust understanding of fluid flow through microscale pore networks of hydrocarbon reservoirs may be consequential to extracting the trillions of barrels of oil and gas still housed in shale formations globally. Models of fluid flow through a pore network that incorporates permeability, capillary pressure, fluid saturation, contact angle, wettability may help to elucidate specific steps to be taken during resource development to optimize petroleum production. Even so, techniques for characterizing these microscale pore networks are hindered by the computational expense of modeling microscale pore network and extrapolation errors caused by oversimplified characterization of pore geometries.

As discussed above, ideal modeling of fluid flow through porous media would allow for precise, quick, and repeatable characterization of a porous media sample. In a case where the porous media sample is, for example, a cylindrical core sample of a rock having a length of six inches and a diameter of one inch, the core sample is likely to have porosity and permeability characteristics that vary across its length and width. This is common in core samples and especially in core samples representative of ultra-tight oil formations. Geological processes that form certain oil-bearing rocks can produce heterogeneous morphological features in the rock that may be present even at a micrometer scale. This is especially true for oil-bearing carbonate rocks, which contain micro-porosities that contribute significantly to the overall porosity of the rock. These microscale morphological features may affect the pore network of the core sample, altering the porosity and permeability throughout a core sample. Thus, accurate characterization of fluid flow through a core sample may depend on precisely ascertained and verifiable microscale geometries sufficient to detect heterogeneous properties of a pore network. Using conventional estimation techniques that cannot consistently capture the heterogeneity and complexity of either the core sample or the fluid-fluid interfaces present therein may result in characterization of a porous media sample that cannot be used to consistently describe fluid flow through the core sample.

According to certain aspects of the present disclosure, to properly develop and test upscaling methods for pore network modeling, techniques for obtaining plug-sized pore networks (e.g., heterogeneous plugs) may be implemented. When imaging a pore space, there may be a trade-off between the imaging resolution and the size of the field of view. Since the images used for network extraction must sufficiently resolve the microscale pore structure of porous media samples, the size of deterministically obtained networks is typically limited.

According to aspects of the present disclosure, the pore network construction procedure described herein may be performed by a processing system architecture comprising at least one or more central processing units (CPUs) operating independently or in combination with one or more graphics processing units (GPUs). Techniques for pore network construction performed by processors operating in sequence may be unable to support the computational load associated with microscale pore networks. Techniques implemented herein may address issues with resolution sufficiency and issues arising from the computational expense of high-resolution pore network extraction. The one or more CPUs and/or the one or more GPUs may perform the procedures according to a non-transitory computer readable medium that causes the one or more CPUs and/or the one or more GPUs to perform any and all steps of the procedure. Each of the one or more CPUs may be utilized in combination with a memory having the computer readable medium stored thereon. Each of the one or more CPUs be utilized in combination with one or more processors. Each of the one or more processors may be parallel processors. Each of the one or more GPUs may be utilized in combination with a memory having the computer readable medium stored thereon. Each of the one or more GPUs be utilized in combination with one or more processors. Each of the one or more processors may be parallel processors. Each of the CPUs and the GPUs may operate independently, or may operate using a message passing interface (MPI) enabling communication between one or more parallel processors for performing the procedure. This may include CPU-CPU communication, CPU-GPU communication, and/or GPU-GPU communication.

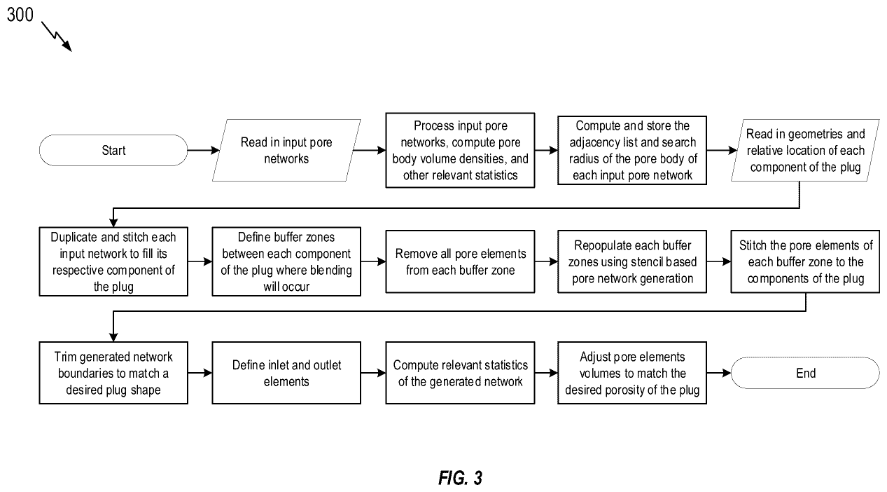

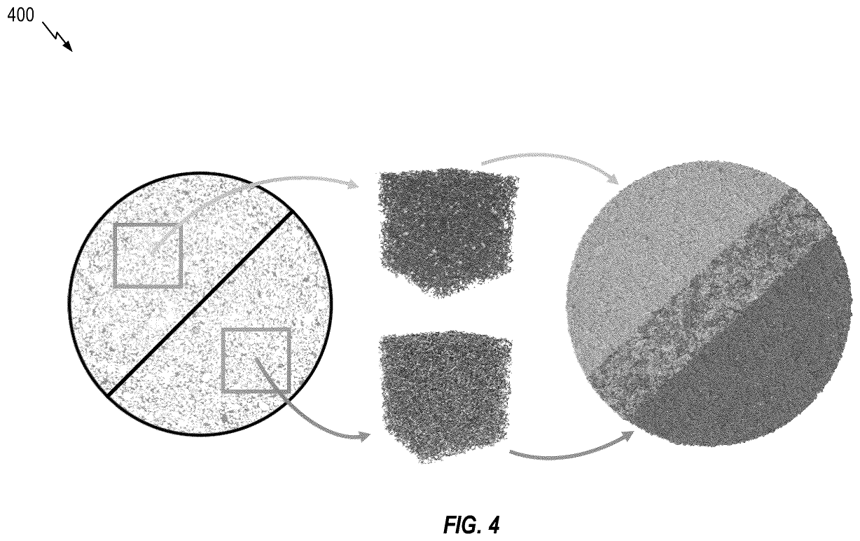

Aspects of the present disclosure provide techniques for pore network duplication and blending. One or more processors (e.g., one or more CPUs) may perform pore network duplication and blending procedures to generate a large-scale representation of a porous media sample (e.g., a digital plug or a heterogeneous plug). A pore network duplication and blending procedure 300 that may be used to construct a representation of a porous media sample is illustrated in FIG. 3. Visualization of the process described in FIG. 3 is further illustrated in FIG. 4.

To perform the procedure, one or more processors perform a pre-processing of the representative pore networks, local pore network duplication and stochastic stencil-based pore network blending, and post-processing of the heterogeneous digital plug. The pre-processing step is illustrated in FIG. 3 and may be performed to read in and process the representative pore networks. To begin the pre-processing step, one or more processors read in one or more input pore networks. Next, the processors process the input pore networks compute the pore body volume densities for each pore network, and calculate any other statistics relevant to the input pore networks. Then, the processors read in geometries and relative locations for each component of a digital heterogeneous plug that the processors may output at the end of the procedure 300. The processors then proceed to a local pore network duplication step.

As illustrated in FIG. 3, the one or more processors duplicate and stitch each input pore network to fill each respective component of the heterogeneous plug. The processors then proceed with the duplication step by defining buffer zone between each component of the digital plug where blending may occur. The processors remove all pore elements from each buffer zone, and repopulate each buffer zone using stencil-based pore network generation. The processors then stitch the pore elements of each buffer zone to the components of the digital plug.

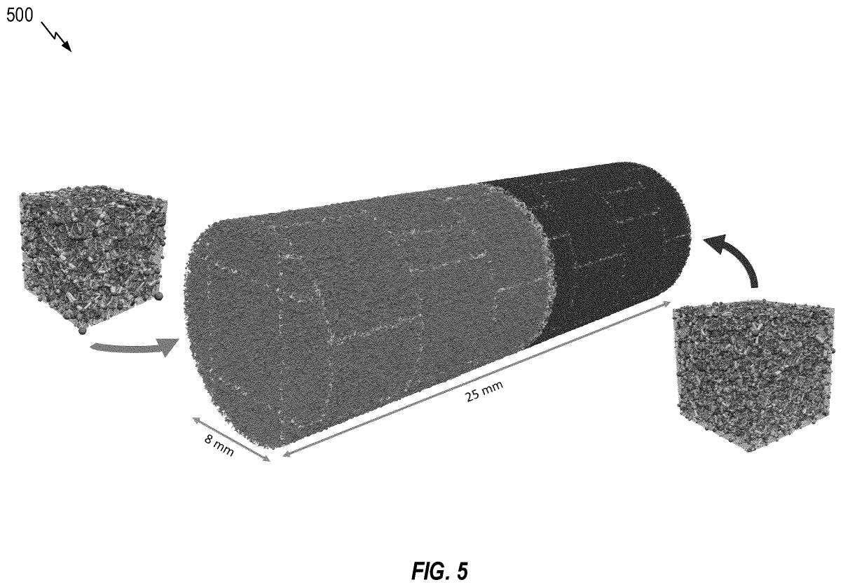

In other words, the processors may duplicate representative pore networks to fill their respective volumes within the heterogeneous digital plug and then merge the representative pore networks using a statistical stitching process. FIG. 4 illustrates a two-dimensional (2D) example of this stitching workflow. In FIG. 4, two pore networks are extracted, evaluated based on overlapping regions (e.g., buffer zones), and stitched together. FIG. 5 illustrates a three-dimensional (3D) example of this stitching workflow. As illustrated in FIG. 5, stitching may be implemented across an entire heterogeneous plug and may be implemented for buffer zones of various sizes and axial orientations. In some cases, stitching may include statistical/stochastic stitching.

Finally, the resulting pore network is post-processed to match the desired geometry, define inlet and outlet pore elements, and adjusted to match the desired porosity data. As illustrated in FIG. 3, the one or more processors trim the generated network boundaries to match a desired heterogeneous plug shape, define inlet and outlet elements, compute relevant statistics of the generated network, and adjust pore element volumes to match the desired porosity of the heterogeneous plug. In some cases, the processors may then end the procedure and output the final heterogeneous plug.

According to certain aspects, at the start of the network duplication and blending procedure, a set of run parameters may be read into the program. The set of parameters may include the desired physical dimensions of the heterogeneous digital plug, the relative locations and volume geometries of each component of the digital plug, as well as the stencil depth limit (e.g., the maximum search depth to consider when defining each pore body's stencil) to be used while performing the stencil-based pore network blending. Additionally, the dimensions of the inlet and outlet buffer zones and excess regions used to define the inlet and outlets of the generated pore network may be provided. Often, the primary inputs to stencil-based stochastic pore network generation are the representative pore networks targeted for representation. The procedure presented here replicates the representative pore networks and allows one or more processors to construct porous networks independent of the porous media sample targeted for replication.

After each representative pore network is read into the program, the one or more processors perform set of pre-processing steps to compute relevant statistics and properties of the input pore network. In some cases, the porosity and clay content of each representative pore network are computed and stored. In some cases, the pore body density of the representative pore network and the volume percentage of the representative pore network that is occupied by its pore bodies may be determined. Symbolically, if the total volume of the representative pore network is Vᵣ, and the set of its pore bodies is represented by Ω^{r}, then the representative pore network's pore body density, D r may be computed as:

$${D}_{r} = \frac{{\sum }_{i ∈ Ω} {v}_{i}}{{V}_{r}}$$

where vᵢ represents the volume of pore body, i.

Consistency with these pore body densities may be used as the primary stopping criteria for the stencil replication process used during the pore network blending step described below.

In certain cases, pore elements that lie on the surface of each representative pore network are identified and deleted. By removing these elements, the new surface of the pore network may consist of pore elements with deficient coordination numbers. This deficiency allows for pore throat connections to be added between neighboring duplicated pore network, and may help to establish buffer zones where stochastic blending may be performed. The remaining pore elements of each pore network may comprise a sample set, the collection of pore elements to be replicated by the one or more processors to create a heterogeneous plug. After each sample set has been determined, a map between each pore body, and its attached pore throats, may be constructed and stored. These maps may allow each stencil of each pore body to be computed efficiently during the stencil duplication step.

The one or more processors then compute and store a search radius of each pore body within the sample set for use whenever statistical stitching is performed. The search radius may represent the maximum distance that can exist between two pore bodies for a pore throat connection to be added between them. The search radius may be computed as an arithmetic mean or a user-defined weighted average of the largest and average distance between a pore body of the sample set and the pore bodies that it shares a pore throat with. In this way, the search radius of each element is unique and reflects the local topology of the representative pore network. During this process, the one or more processors also accumulate and store the average spacing between each connected pore body of the sample set.

According to certain aspects, the one or more processors then fill the geometries of each component of the heterogeneous plug by repetitively duplicating the sample set of the representative pore network that is assigned to the heterogeneous plug. The one or more processors may extend these geometric boundaries to completely fill the geometry during the duplication step. The space between each duplicated sample set is determined using a fraction of the average distance between connected pores. Often, the orientation of each duplication is independent of this process but is chosen to ensure an even spacing between its duplicated neighbors. After the geometry of a component has been filled with duplicated sample sets, the one or more processors trim the boundaries to match its desired dimensions.

In some cases, pore bodies that lie on the surface of each duplicated sample set may have coordination numbers that are less than their desired value. To merge each sample set together, the one or more processors use these coordination number deficiencies and employ a statistical stitching process to add well characterized pore throat connections between each duplicated sample set. This concept is illustrated in FIG. 5, where a heterogeneous digital plug generated with two components is shown with pore throat connections added during the stitching process highlighted.

Stitching begins by the processors defining a stitch queue consisting of pore bodies of the generated network whose coordination number is less than their corresponding defining element of the input network. Each element of the stitch queue is then assigned a desired coordination number based on the coordination number of its corresponding defining element in the sample sets. The processors then select a pore body from the stitch queue and add pore throat connections between it and its neighboring pore bodies in the following way. In some cases, the processors may first identify the pore bodies of the stich queue that do not already share a pore throat connection with the selected pore body and are within its precomputed search radius. The processors then rank this set of pore bodies using a weighted average of the distance between them, and the absolute difference between their spherical radii. In other words, the processors prioritize connecting pore bodies that are close to each other and have similar radii. The processors may then sequentially connect the selected pore body with its highest-ranking neighbors until either its desired coordination number is reached, or a connection between every element within its search radius has been added. These connections are established by duplicating pore throats from the representative pore network that preserve the aspect ratios of both elements.

In some cases, pᵢ may represent the pore body of the representative pore network from which the selected pore body was duplicated, and Ψᵢ may represent the set of pore throats that are connected to it. Further, tᵢⱼ∈Ψᵢ, may denote an arbitrary pore throat that connects pᵢ with pⱼ, the second pore body of the representative pore network with which tᵢⱼ is connected. The element of Ψᵢ may be copied to define a pore throat connection between the selected pore throat and its highest-ranking neighbor is then determined by the following equation:

$$t = {min}_{{t}_{ij} ∈ Ψ} \vert R - {R}_{j} \vert$$

where Rⱼ and R are the spherical radii of pⱼ and the highest-ranking neighbor, respectively. After t has been determined, the processors then add a pore throat connection between the selected pore body and its highest-ranking neighbor by duplicating t and updating its length information to reflect the relative positions of these two pore bodies. The coordination number of each pore body is then incrementally increased. A pore body may be removed from the stitch queue when its coordination number equals its desired value. This process may be repeated on every element of the stitch queue until every viable pore throat connection has been established.

After each component of the heterogeneous plug is filled using the local pore network duplication process, the one or more processors stochastically blend them together using a stencil replication procedure.

According to certain aspects, the one or more processors may perform the stencil replication procedure according to the following steps. First, the processors populate the generated pore network by randomly selecting pore bodies from the sample set and computing random positions within the desired physical dimensions of the generated network to place them during a stencil replication process. After a pore body and its location have been determined, the processors may check if a pore body's placement and spherical radius would overlap with previously generated pore bodies. If no overlaps exist, then the selected pore body is added to the generated network, and the processors identify the pore body as a seed element for the duplicated stencil. A breadth-first search (BF S) or a depth-first search (DFS) is performed by the processors to identify the surrounding layer of pore elements of the sample set that are connected to the seed element. This set of elements initially populates the add queue of the duplicated stencil. Each pore body of the add queue is then evaluated, and its relative position to the seed element within the generated pore network is computed. If the selected element of the add queue lies inside the domain of the generated pore network, and does not overlap with previously placed pore bodies, then it is added to the generated pore network. A BFS or DFS is then performed to identify the pore bodies of the sample set that are connected to the selected pore body. If an element of this layer has already been copied into the duplicated stencil, then the pore throat that connects them in the sample set is also duplicated in the generate pore network. If a connected element has not already been added, and the layer depth limit has not been reached, then it may be inserted into the add queue. The size of the add queue increases until each viable element of the sample set, within the layer depth search limit, has been added to the add queue. After each pore-element of the add queue has been accessed, a new seed element may be selected from the sample set and the process is repeated to stochastically duplicate a next stencil.

According to certain aspects, pore bodies with a large coordination numbers are more likely to be duplicated since they belong to a larger number of stencils. To prevent oversampling these subsets of the representative pore network, the processors may temporarily remove pore bodies from the sample list after they have been duplicated in the generated pore network. These pore bodies are periodically repopulated back into the sample set after a user defined percentage of the original sample set has been duplicated.

Termination of the stochastic pore network stencil replication process may be determined by one or more processors using the pore body volume of the generated pore network. The one or more processors may define the desired pore body volume, ρ_{g}, to be the pore body density of the representative pore network multiplied by the desired volume of the generated pore network (ρ_{g}=Dᵣ·V_{g}). After a stencil has been duplicated, the pore body volume of the generated pore network may be computed and compared against the desired pore body volume. When the pore body volume of the generated pore network is larger than ρ_{g}, the stochastic pore network stencil replication process is stopped, as no more pore bodies are required to define the generated pore network.

After the one or more processors complete the stencil duplication step, the processors deem the number of pore bodies replicated to be sufficient. During the statistical stitching process, the processors may add connections between each duplicated stencil and thereby may add a sufficient number of pore throats to the generated pore network. Notably, after stochastic stencil duplication, throat connections between each duplicated stencil may not exist, and pore bodies on the outer layer of each stencil may have coordination numbers that are less than the element of the representative pore network from which they were duplicated.

In some cases, the geometries of buffer zones between neighboring components may be identified and the previously duplicated pore elements within them are removed. The dimensions of these buffer zones may be either user defined, or their widths may be computed as a multiple of the average distance between the pores of each component. The buffer zone is then populated.

At this point, the generated pore network (e.g., the heterogeneous plug) may consists of an optimal number of both pore bodies and pore throat connections. In the post-processing step, the processors fit the generated pore network to its desired shape and dimensions, create boundary elements, and match its porosity with the representative pore network.

The generated pore network may be populated in a cuboid domain that is slightly larger than the desired physical dimensions that were read in. This is done to ensure that the generated pore network faithfully recreates the internal structure of the representative pore network along its boundaries. In many cases, the processors may remove elements of the generated pore network that lie outside of its desired domain and shape. For example, if the desired pore network should be cylindrical in shape, the distance of each pore body from the center of the generated pore network and the center of the cylinder is computed. If pore elements lie outside the radius of the desired cylindrical shape then the pore elements are removed from the network.

To define inlet pores, outlet pores, and buffer zones, the one or more processors define a mid-plane that is perpendicular to the direction of flow at the desired location of the inlet. Any pore throat that intersects this mid-plane is classified as an inlet pore throat, and all pore elements that lie within the excess region (i.e., between the mid-plane and the outer boundary of the generated pore network) are removed. If more than one inlet pore throat is attached to the same pore body, then the one with the largest spherical radius may be kept. A similar process may be used to define the outlet boundary. In some cases, the seed element for each duplicated stencil may be chosen randomly from the sample set of each of the neighboring components. This may allow the buffer zone to be stochastically filled with pore elements from each component of the representative pore network. Termination of the stochastic pore network stencil replication process may be determined using the average of each components pore body volume. Afterwards, the one or more processors employ a statistical stitching process described herein to add well-characterized pore throat connections between each duplicated sample set.

At this point, the heterogeneous plug may consist of an optimal number of both pore bodies and pore throat connections. In a post-processing step, the one or more processors may fit the generated pore network to its desired shape and dimensions, create boundary elements, and match its porosity with representative pore networks. According to certain aspects, the porosity of the heterogeneous digital plug may be determined. First, if a desired porosity value for the digital plug is known, then the value can be directly compared against the computed porosity of the heterogeneous digital plug. Alternatively, if a desired porosity is unknown, then a weighted average of each representative pore network's porosity can be used. In one case, if the void volume percentage or clay content of the generated network does not match their desired values, then a small adjustment may be performed by the one or more processors to each pore element so that the desired porosity is achieved. In certain cases, ϕᵣ and ϕ_{g} may represent the porosity of the representative and generated pore network, respectively. Accordingly, the one or more processors may update the volume of each pore element to be α·ϕᵣ·v/ϕ_{g}, where v is the current volume of the pore element and α is a random variable ranging from 0.5 to 1.5 in value. Afterwards, the summation of each pore elements volume will sum to a value that is close to ϕᵣ.

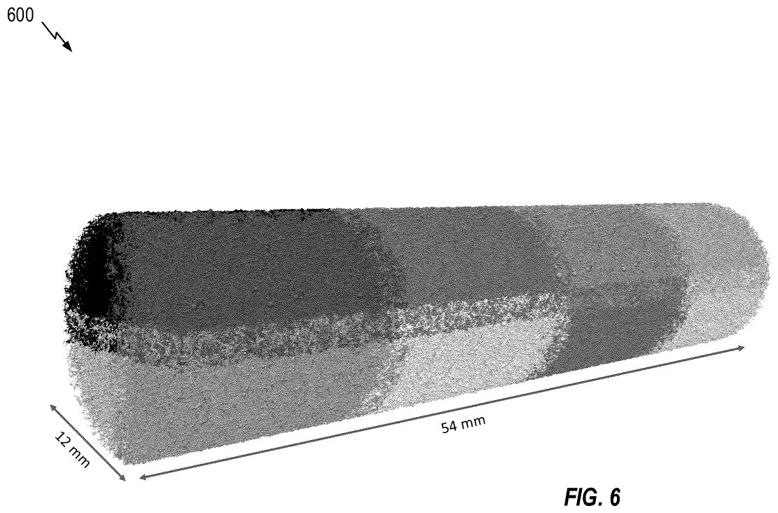

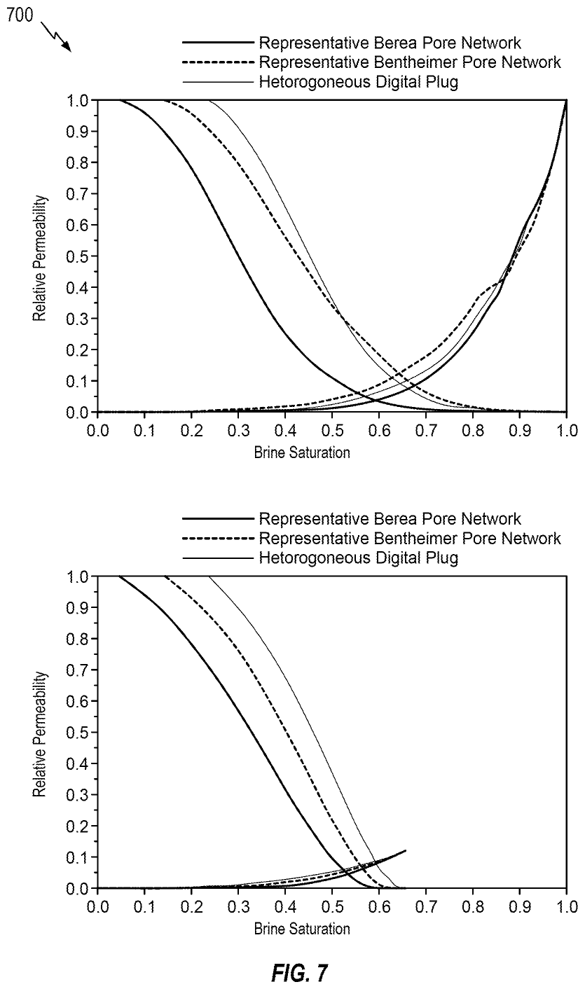

FIG. 6 illustrates a visualization of a heterogeneous digital plug that was obtained using representative pore networks of sample sandstones. To demonstrate the properties of pore networks generated with this method, predictions of primary drainage and imbibition relative permeability curves for this heterogeneous digital plug are provided in FIG. 7. For comparison, the relative permeability curves of the sample pore networks from which the digital plug was generated are also provided in FIG. 7.

### Example Methods

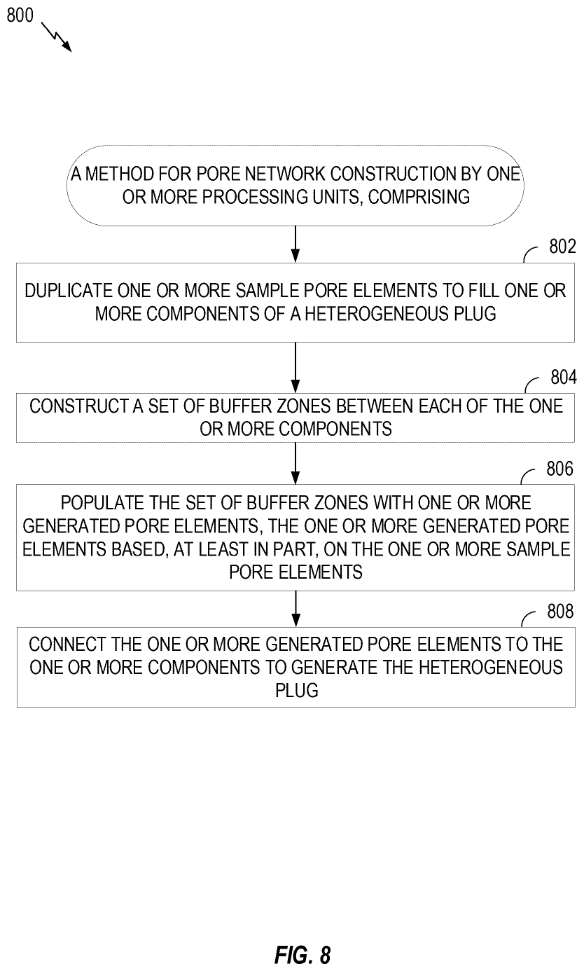

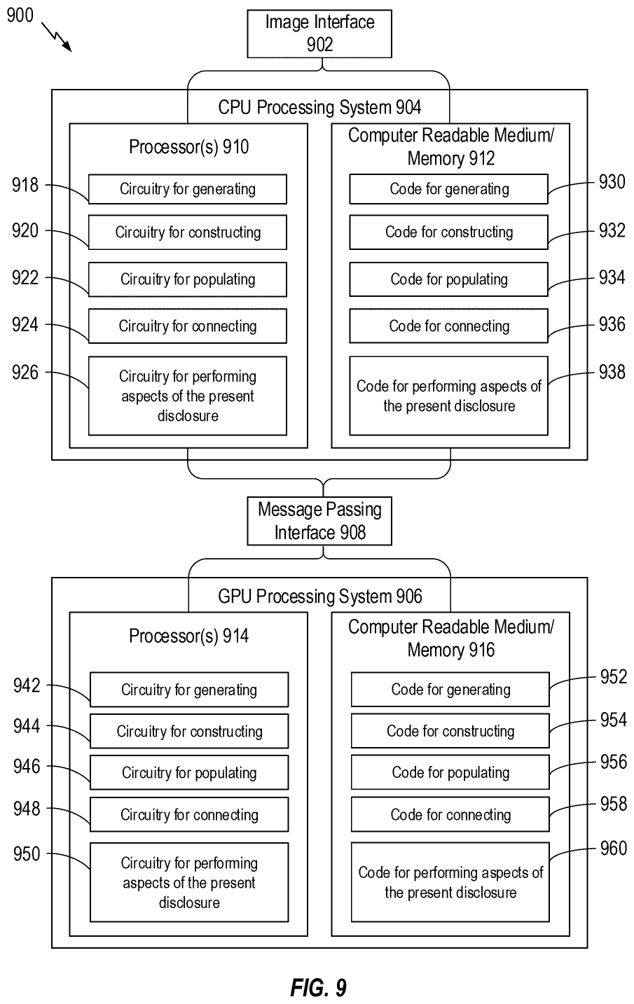

FIG. 8 depicts a method 800 for pore network construction by one or more CPUs, such as the CPUs of the device 900 of FIG. 9.

Method 800 begins at 802 with one or more CPUs generating one or more sample pore elements to fill one or more components of a heterogeneous plug. In some cases, duplicating the one or more sample pore elements includes selecting a target pore body from the one or more sample pore elements, adding the target pore body to one of the one or more components of the heterogeneous plug, and replicating one or more pore throat connections from the representative pore network substantially within the one or more components, the one or more pore throat connections disposed between the target pore body and one or more duplicated neighbors of the target pore body.

Method 800 continues to step 804 with one or more CPUs constructing a set of buffer zones between each of the one or more components.

Method 800 continues to step 806 with one or more CPUs populating the set of buffer zones with one or more generated pore elements, the one or more generated pore elements based, at least in part, on the one or more sample pore elements. In some cases, populating the set of buffer zones includes populating the buffer zones using stencil based stochastic pore network generation.

Method 800 continues to step 808 with one or more CPUs connecting the one or more generated pore elements to the one or more components to generate the heterogeneous plug. In some cases, connecting the one or more generated pore elements to the one or more components comprises generating a stitch queue of one or more stitch pore bodies, the one or more stitch pore bodies comprising a portion of one or more generated pore bodies, the portion classified based on a coordination number deficiency, selecting a target stitch pore body from the stitch queue, identifying one or more neighboring stitch pores, the one or more neighboring stitch pores identified according to a search radius assigned to the target stitch pore, ranking the one or more neighboring stitch pores to classify one of the one or more neighboring stich pores as a highest-ranked neighbor pore, connecting the highest-ranked neighbor pore and the target stitch pore, and processing each of the one or more pore stitch bodies in the stitch queue to define the heterogeneous plug. In some cases, the heterogeneous plug is generated based on a facies map.

Method 800 may further include one or more CPUs obtaining a representative pore network having one or more representative pore elements, the representative pore network corresponding to a porous media sample. Obtaining may include defining, for the representative pore network, porosity values, clay content values, a pore body density, and a volume percentage occupied by the one or more sample pore elements, and removing, from the one or more sample pore elements, a set of surface pore elements to generate the one or more sample pore elements. Obtaining may further include generating a search radius for each of the one or more sample pore elements, and generating an adjacency list for each of the one or more sample pore elements. In some cases, the search radius is an arithmetic mean of a largest distance and an average distance between a first pore body of the one or more sample pore elements and any other pore body to which the first pore body is connected. In some cases, the representative pore network has known dimensions.

Method 800 may further include outputting the heterogeneous plug.

Method 800 may further include processing the heterogeneous plug, based on one or more parameters, to align substantially with properties of a representative pore network. In some cases, the one or more parameters comprise at least one of a desired shape, desired dimensions, and a target porosity. In some cases, the target porosity includes a known porosity value of a representative pore network or a weighted average porosity value.

Method 800 may further include removing a first portion of one or more generated pore elements from the heterogeneous plug, the first portion of one or more generated pore elements being outside of a target shape, a target domain, or both the target shape and the target domain, defining a mid-plane substantially perpendicular to a direction of flow, based on the mid-plane, defining one or more inlet pores and one or more outlet pores, and adjusting a first porosity of the heterogeneous plug to substantially align with a second porosity of a representative pore network.

In one aspect, method 800, or any aspect related to it, may be performed by an apparatus, such as device 900 of FIG. 9, which includes various components operable, configured, or adapted to perform the method 800. Device 900 is described below in further detail.

Note that FIG. 8 is just one example of a method, and other methods including fewer, additional, or alternative steps are possible consistent with this disclosure.

### Example Device

FIG. 9 depicts aspects of an example porous media device 900. In some aspect, the device 900 comprises one or more CPUs, one or more GPUs, or both as described above with respect to FIG. 8.

The device 900 includes a CPU processing system 904 coupled to an image interface 902 (e.g., a user interface or and/or an image generator such as a commercial micro-CT scanner). The CPU processing system 904 may be configured to perform processing functions for the device 900, including pore network extraction performed by the device 900.

The CPU processing system 904 includes one or more processors 910. The one or more processors 910 are coupled to a computer-readable medium/memory 912 via a bus. The one or more processors 910 and the computer-readable medium/memory 912 may communicate with the one or more processor 914 and the computer-readable medium/memory 916 of the GPU processing system 906 via a message passing interface (MPI) 908. In certain aspects, the computer-readable medium/memory 912 is configured to store instructions (e.g., computer-executable code) that when executed by the one or more processors 910, cause the one or more processors 910 to perform the method 800 described with respect to FIG. 8, or any aspect related to it. Note that reference to a processor performing a function of device 900 may include one or more processors performing that function of device 900.

In the depicted example, computer-readable medium/memory 912 stores code (e.g., executable instructions) 930-938 for performing techniques described herein, according to aspects of the present disclosure. Processing of the code 930-938 may cause the device 900 to perform the method 800 described with respect to FIG. 8, or any aspect related to it, including duplicating, generating, constructing, populating, connecting, obtaining, outputting, defining, removing, selecting, adding, replicating, identifying, ranking, processing, adjusting, and any other suitable performance.

The one or more processors 910 include circuitry configured to implement (e.g., execute) the code stored in the computer-readable medium/memory 912, including circuitry 918-926 for performing techniques described herein, according to aspects of the present disclosure. Processing with circuitry 918-926 may cause the device 900 to perform the method 800 described with respect to FIG. 8, or any aspect related to it, including duplicating, generating, constructing, populating, connecting, obtaining, outputting, defining, removing, selecting, adding, replicating, identifying, ranking, processing, adjusting, and any other suitable performance.

Various components of the device 900 may provide means for performing the method 800 described with respect to FIG. 8, or any aspect related to it.

The device 900 includes a GPU processing system 906. The GPU processing system 906 may be configured to perform processing functions for the device 900, pore network extraction performed by the device 900.

The GPU processing system 906 includes one or more processors 914. The one or more processors 914 are coupled to a computer-readable medium/memory 916 via a bus. The one or more processors 914 and the computer-readable medium/memory 916 may communicate with the one or more processor 910 and the computer-readable medium/memory 912 of the CPU processing system 904 via an MPI 908. In certain aspects, the computer-readable medium/memory 916 is configured to store instructions (e.g., computer-executable code) that when executed by the one or more processors 914, cause the one or more processors 914 to perform the method 800 described with respect to FIG. 8, or any aspect related to it. Note that reference to a processor performing a function of device 900 may include one or more processors performing that function of device 900.

In the depicted example, computer-readable medium/memory 916 stores code (e.g., executable instructions) for performing certain functions according to aspects of the present disclosure 952-960. Processing of the code 952-960 may cause the device 900 to perform the method 800 described with respect to FIG. 8, or any aspect related to it, including duplicating, generating, constructing, populating, connecting, obtaining, outputting, defining, removing, selecting, adding, replicating, identifying, ranking, processing, adjusting, and any other suitable performance.

The one or more processors 914 include circuitry configured to implement (e.g., execute) the code stored in the computer-readable medium/memory 916, including circuitry for performing certain functions according to aspects of the present disclosure 942-950. Processing with circuitry 942-950 may cause the device 900 to perform the method 800 described with respect to FIG. 8, or any aspect related to it, including duplicating, generating, constructing, populating, connecting, obtaining, outputting, defining, removing, selecting, adding, replicating, identifying, ranking, processing, adjusting, and any other suitable performance.

Various components of the device 900 may provide means for performing the method 800 described with respect to FIG. 8, or any aspect related to it.

### Example Aspects

Implementation examples are described in the following numbered clauses:

Aspect 1: A method for generating a heterogeneous plug for a porous media sample by one or more central processing units (CPUs), comprising: duplicating or generating one or more sample pore elements to fill one or more components of a heterogeneous plug, constructing a set of buffer zones between each of the one or more components, populating the set of buffer zones with one or more generated pore elements, the one or more generated pore elements based, at least in part, on the one or more sample pore elements, and connecting the one or more generated pore elements to the one or more components to generate the heterogeneous plug.

Aspect 2: The method of aspect 1, further comprising obtaining a representative pore network having one or more representative pore elements, the representative pore network corresponding to a porous media sample.

Aspect 3: The method of aspect 2, wherein obtaining the representative pore network comprises: defining, for the representative pore network, porosity values, clay content values, a pore body density, and a volume percentage occupied by the one or more sample pore elements, and removing, from the one or more sample pore elements, a set of surface pore elements to generate the one or more sample pore elements.

Aspect 4: The method of any one of aspects 2 and 3, wherein obtaining the representative pore network comprises: generating a search radius for each of the one or more sample pore elements, and generating an adjacency list for each of the one or more sample pore elements.

Aspect 5: The method of aspect 4, wherein the search radius is an arithmetic mean of a largest distance and an average distance between a first pore body of the one or more sample pore elements and any other pore body to which the first pore body is connected.

Aspect 6: The method of any one of aspects 2 through 5, wherein generating the one or more sample pore elements further comprises selecting a target pore body from the one or more sample pore elements, adding the target pore body to one of the one or more components of the heterogeneous plug, and replicating one or more pore throat connections from the representative pore network substantially within the one or more components, the one or more pore throat connections disposed between the target pore body and one or more duplicated neighbors of the target pore body.

Aspect 7: The method of any one of aspects 2 through 6, wherein the representative pore network has known dimensions.

Aspect 8: The method of any one of aspects 1 through 7, further comprising outputting the heterogeneous plug.

Aspect 9: The method of any one of aspects 1 through 8, wherein populating the set of buffer zones comprises populating the buffer zones using stencil based stochastic pore network generation.

Aspect 10: The method of any one of aspects 1 through 9, wherein connecting the one or more generated pore elements to the one or more components comprises: generating a stitch queue of one or more stitch pore bodies, the one or more stitch pore bodies comprising a portion of one or more generated pore bodies, the portion classified based on a coordination number deficiency, selecting a target stitch pore body from the stitch queue, identifying one or more neighboring stitch pores, the one or more neighboring stitch pores identified according to a search radius assigned to the target stitch pore, ranking the one or more neighboring stitch pores to classify one of the one or more neighboring stich pores as a highest-ranked neighbor pore, connecting the highest-ranked neighbor pore and the target stitch pore, and processing each of the one or more pore stitch bodies in the stitch queue to define the heterogeneous plug.

Aspect 11: The method of any one of aspects 1 through 10, wherein the heterogeneous plug is generated based on a facies map.

Aspect 12: The method of any one of aspects 1 through 11, the method further comprising processing the heterogeneous plug, based on one or more parameters, to align substantially with properties of a representative pore network.

Aspect 13: The method of aspect 12, wherein the one or more parameters comprise at least one of a desired shape, desired dimensions, and a target porosity.

Aspect 14. The method of aspect 13, wherein the target porosity comprises: a known porosity value of a representative pore network, or a weighted average porosity value.

Aspect 15: The method of any one of aspects 12 through 14, further comprising: removing a first portion of one or more generated pore elements from the heterogeneous plug, the first portion of one or more generated pore elements being outside of a target shape, a target domain, or both the target shape and the target domain, defining a mid-plane substantially perpendicular to a direction of flow, based on the mid-plane, defining one or more inlet pores and one or more outlet pores, and adjusting a first porosity of the heterogeneous plug to substantially align with a second porosity of a representative pore network.

Aspect 16: The method of any one of aspects 1 through 16, wherein the porous media sample is a rock sample.

Aspect 17: An apparatus, comprising: a memory comprising executable instructions; and a processor configured to execute the executable instructions and cause the apparatus to perform a method in accordance with any one of Aspects 1-16.

Aspect 18: An apparatus, comprising means for performing a method in accordance with any one of Aspects 1-16.

Aspect 19: A non-transitory computer-readable medium comprising executable instructions that, when executed by a processor of an apparatus, cause the apparatus to perform a method in accordance with any one of Aspects 1-16.

Aspect 20: A computer program product embodied on a computer-readable storage medium comprising code for performing a method in accordance with any one of Aspects 1-16.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). The singular forms “a,” “an,” and “the” include plural referents, unless the context clearly dictates otherwise. Within a claim, reference to an element in the singular is not intended to mean “one and only one” unless specifically so stated, but rather “one or more.” Unless specifically stated otherwise, the term “some” refers to one or more.

As used herein, the term “determining” encompasses a wide variety of actions. For example, “determining” may include calculating, computing, processing, deriving, investigating, updating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, simulating, choosing, establishing, and the like.

The methods disclosed herein comprise one or more operations or actions for achieving the methods. The method operations and/or actions may be interchanged with one another without departing from the scope of the claims. In other words, unless a specific order of operations or actions is specified, the order and/or use of specific operations and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in the figures, those operations may have corresponding counterpart means-plus-function components with similar numbering.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

Unless defined otherwise, all technical and scientific terms used have the same meaning as commonly understood by one of ordinary skill in the art to which these systems, apparatuses, methods, processes and compositions belong.

The following claims are not intended to be limited to the embodiments provided but rather are to be accorded the full scope consistent with the language of the claims.

What is claimed is:

1. A method for generating a heterogeneous plug for a porous media sample by one or more central processing units (CPUs), comprising:
duplicating one or more sample pore elements to fill one or more components of a heterogeneous plug;
constructing a set of buffer zones between each of the one or more components;
populating the set of buffer zones with one or more generated pore elements, the one or more generated pore elements based, at least in part, on the one or more sample pore elements; and
connecting the one or more generated pore elements to the one or more components to generate the heterogeneous plug.

2. The method of claim 1, further comprising obtaining a representative pore network having one or more representative pore elements, the representative pore network corresponding to a porous media sample.

3. The method of claim 2, wherein obtaining the representative pore network comprises:
defining, for the representative pore network, porosity values, clay content values, a pore body density, and a volume percentage occupied by the one or more sample pore elements; and
removing, from the one or more sample pore elements, a set of surface pore elements to generate the one or more sample pore elements.

4. The method of claim 2, wherein obtaining the representative pore network comprises:
generating a search radius for each of the one or more sample pore elements; and
generating an adjacency list for each of the one or more sample pore elements.

5. The method of claim 4, wherein the search radius is an arithmetic mean of a largest distance and an average distance between a first pore body of the one or more sample pore elements and any other pore body to which the first pore body is connected.

6. The method of claim 2, wherein duplicating the one or more sample pore elements further comprises:
selecting a target pore body from the one or more sample pore elements;
adding the target pore body to one of the one or more components of the heterogeneous plug; and
replicating one or more pore throat connections from the representative pore network substantially within the one or more components, the one or more pore throat connections disposed between the target pore body and one or more duplicated neighbors of the target pore body.

7. The method of claim 2, wherein the representative pore network has known dimensions.

8. The method of claim 1, further comprising outputting the heterogeneous plug.

9. The method of claim 1, wherein populating the set of buffer zones comprises populating the buffer zones using stencil based stochastic pore network generation.

10. The method of claim 1, wherein connecting the one or more generated pore elements to the one or more components comprises:
generating a stitch queue of one or more stitch pore bodies, the one or more stitch pore bodies comprising a portion of one or more generated pore bodies, the portion classified based on a coordination number deficiency;
selecting a target stitch pore body from the stitch queue;
identifying one or more neighboring stitch pores, the one or more neighboring stitch pores identified according to a search radius assigned to the target stitch pore;
ranking the one or more neighboring stitch pores to classify one of the one or more neighboring stich pores as a highest-ranked neighbor pore;
connecting the highest-ranked neighbor pore and the target stitch pore; and
processing each of the one or more pore stitch bodies in the stitch queue to define the heterogeneous plug.

11. The method of claim 1, wherein the heterogeneous plug is generated based on a facies map.

12. The method of claim 1, the method further comprising processing the heterogeneous plug, based on one or more parameters, to align substantially with properties of a representative pore network.

13. The method of claim 12, wherein the one or more parameters comprise at least one of a desired shape, desired dimensions, and a target porosity.

14. The method of claim 13, wherein the target porosity comprises:
a known porosity value of a representative pore network; or
a weighted average porosity value.

15. The method of claim 12, further comprising:
removing a first portion of one or more generated pore elements from the heterogeneous plug, the first portion of one or more generated pore elements being outside of a target shape, a target domain, or both the target shape and the target domain;
defining a mid-plane substantially perpendicular to a direction of flow;
based on the mid-plane, defining one or more inlet pores and one or more outlet pores; and
adjusting a first porosity of the heterogeneous plug to substantially align with a second porosity of a representative pore network.

16. The method of claim 1, wherein the porous media sample is a rock sample.

17. An apparatus, comprising: a memory comprising executable instructions, and one or more processors configured to execute the executable instructions and cause the apparatus to:
duplicate one or more sample pore elements to fill one or more components of a heterogeneous plug;
construct a set of buffer zones between each of the one or more components;
populate the set of buffer zones with one or more generated pore elements, the one or more generated pore elements based, at least in part, on the one or more sample pore elements; and
connect the one or more generated pore elements to the one or more components to generate the heterogeneous plug.

18. The apparatus of claim 17, the one or more processors further configured to obtain a representative pore network having one or more representative pore elements, the representative pore network corresponding to a porous media sample.

19. The apparatus of claim, the one or more processors further configured to process the heterogeneous plug, based on one or more parameters, to align substantially with properties of a representative pore network.

20. A non-transitory computer-readable medium comprising executable instructions that, when executed by one or more processors of an apparatus, cause the apparatus to:
duplicate one or more sample pore elements to fill one or more components of a heterogeneous plug;
construct a set of buffer zones between each of the one or more components;
populate the set of buffer zones with one or more generated pore elements, the one or more generated pore elements based, at least in part, on the one or more sample pore elements; and
connect the one or more generated pore elements to the one or more components to generate the heterogeneous plug.
